(19) United States
(12) Patent Application Publication
(10) Pub. No.: US 2025/0372358 A1
(43) Pub. Date: Dec. 4, 2025

(54) SUBSTRATE PROCESSING SYSTEM AND SUBSTRATE PROCESSING METHOD FOR ACQUIRING PLASMA EMISSION DATA INSIDE A CHAMBER AND PREDICTING A STATE INSIDE THE CHAMBER BY INPUTTING THE EMISSION DATA

(71) Applicant: Tokyo Electron Limited, Tokyo (JP)

(72) Inventors: Ryu NAGAI, Miyagi (JP); Koki TANAKA, Miyagi (JP)

(73) Assignee: Tokyo Electron Limited, Tokyo (JP)

(21) Appl. No.: 19/305,831

(22) Filed: Aug. 21, 2025

Related U.S. Application Data
(63) Continuation of application No. PCT/JP2024/005450, filed on Feb. 16, 2024.

(30) Foreign Application Priority Data
Mar. 1, 2023 (JP) 2023-031125

(51) Int. Cl. H01J 37/32

(52) U.S. Cl. CPC H01J 37/32972; H01J 37/32926

(57) ABSTRACT

A substrate processing system acquires plasma emission data inside a chamber, and predicts a state inside the chamber by inputting the acquired plasma emission data to a trained model that has learned a relationship between the plasma emission data and information indicating the state inside the chamber.

### CROSS-REFERENCE TO RELATED APPLICATIONS

This application is a continuation application of International Application No. PCT/JP2024/005450, filed on Feb. 16, 2024 and designated the U.S., which is based upon and claims priority to Japanese Patent Application No. 2023-031125, filed on Mar. 1, 2023, the entire contents of each of which are incorporated herein by reference.

### BACKGROUND

### 1. Field of the Invention

The present disclosure relates to substrate processing systems, and substrate processing methods.

### 2. Description of the Related Art

In a substrate processing apparatus, a state inside a chamber is monitored in real time. For example, Japanese Laid-Open Patent Publication No. 2003-197609 proposes a method of monitoring a plasma processing apparatus, which predicts a control parameter or an apparatus state parameter during processing by applying a plasma reflection parameter obtained when a wafer is processed using high-frequency power to a model formula.

### SUMMARY

The present disclosure provides a technique for predicting a state inside a chamber based on plasma emission data.

According to an aspect of the present disclosure, a substrate processing system includes a data acquisition unit configured to acquire plasma emission data inside a chamber; and a state prediction unit configured to predict a state inside the chamber by inputting the plasma emission data acquired by the data acquisition unit to a trained model that has learned a relationship between the plasma emission data and information indicating the state inside the chamber.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

The scope of the present disclosure is best understood from the following detailed description of exemplary embodiments when read in conjunction with the accompanying drawings.

FIG. 1 is a block diagram illustrating an example of an overall configuration of a substrate processing system;

FIG. 2 is a schematic diagram illustrating an example of a hardware configuration of the substrate processing apparatus;

FIG. 3 is a block diagram illustrating an example of a hardware configuration of a computer;

FIG. 4 is a block diagram illustrating an example of a functional configuration of the substrate processing system;

FIG. 5 is a flow chart illustrating an example of an information processing method;

FIG. 6 is a diagram illustrating an example of a training data collection procedure;

FIG. 7 is a block diagram illustrating an example of a prediction model;

FIG. 8 is a diagram illustrating an example of a prediction accuracy for a residual moisture content;

FIG. 9 is a diagram illustrating an example of impact levels of wavelength bands on residual moisture content prediction;

FIG. 10 is a diagram illustrating an example of a prediction accuracy for a parts wear rate; and

FIG. 11 is a diagram illustrating an example of impact levels of wavelength bands on a parts wear rate prediction.

### DETAILED DESCRIPTION

Hereinafter, embodiments of the present disclosure will be described with reference to the drawings. In the drawings, the same constituent elements are designated by the same reference numerals, and a redundant description thereof may be omitted.

### Embodiment

An embodiment of the present disclosure relates to a substrate processing system that predicts a state inside a chamber (hereinafter, also referred to as a “chamber state”) in a substrate processing apparatus that processes a substrate, which is an example of a workpiece, inside the chamber. The substrate processing apparatus according to the present embodiment is an etching apparatus that performs an etching process on the substrate by controlling a plasma state inside the chamber, for example. However, the substrate processing apparatus is not limited to the etching apparatus, and may be any kind of apparatus as long as the apparatus performs the plasma process on the substrate.

In the substrate processing apparatus, a dedicated sensor may be installed in the substrate processing apparatus in order to measure an extent of parts (or components) wear rate inside the chamber or a variation in a residual gas content inside the chamber in real time. However, installing a physical sensor in the substrate processing apparatus involves a high technical difficulty in developing the sensor itself, and a large development cost. Further, installing the physical sensor increases a manufacturing cost of the substrate processing apparatus. In contrast, a virtual sensor estimates data that is difficult to directly measure from other information using software. Hence, by using the virtual sensor, it is possible to estimate the chamber state in real time, and to prevent an increase in the manufacturing cost of the substrate processing apparatus.

The present embodiment provides a substrate processing system capable of predicting a chamber state based on plasma emission data. In one aspect of the present disclosure, the substrate processing system according to the present embodiment uses a sensor provided in an existing substrate processing apparatus, and thus, it is possible to easily implement a virtual sensor for estimating the chamber state at a low cost without having to newly install a dedicated sensor.

### <System Configuration>

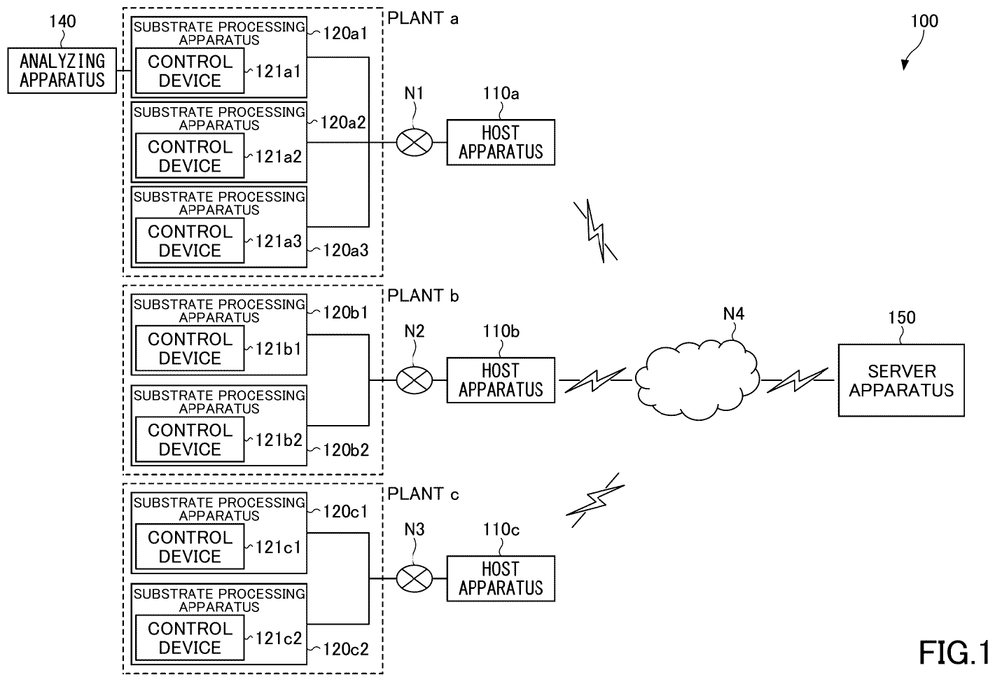

An overall configuration of the substrate processing system according to the present embodiment will be described with reference to FIG. 1. FIG. 1 is a block diagram illustrating an example of the overall configuration of the substrate processing system according to the present embodiment.

As illustrated in FIG. 1, a substrate processing system 100 includes substrate processing apparatuses 120a1 through 120a3 and control devices 121a1 through 121a3, provided in a plant “a”. The substrate processing apparatuses 120al through 120a3 and the control devices (i.e., control circuitry) 121a1 through 121a3 are connected by a wired or wireless connection, respectively.

In addition, the substrate processing system 100 includes substrate processing apparatuses 120b1 and 120b2 and control devices 121b1 and 121b2, provided in a plant “b”. The substrate processing apparatuses 120b1 and 120b2 and the control devices 121b1 and 121b2 are connected by a wired or wireless connection, respectively.

Further, the substrate processing system 100 includes substrate processing apparatuses 120c1 and 120c2 and control devices 121c1 and 121c2, provided in a plant “c”. The substrate processing apparatuses 120c1 and 120c2 and the control devices 121c1 and 121c2 are connected by a wired or wireless connection, respectively.

The substrate processing apparatuses 120a1 through 120a3, the substrate processing apparatuses 120b1 and 120b2, and the substrate processing apparatuses 120c1 and 120c2 are connected to host apparatuses 110a, 110b, and 110c via networks N1, N2, and N3, respectively. The substrate processing apparatuses 120a1 through 120a3 perform a substrate processing under control of the control devices 121a1 through 121a3, respectively, based on instructions from the host apparatus 110a. The substrate processing apparatuses 120b1 and 120b2 perform a substrate processing under control of the control devices 121b1 and 121b2, respectively, based on instructions from the host apparatus 110b. The substrate processing apparatuses 120c1 and 120c2 performs a substrate processing under control of the control devices 121c1 and 121c2, respectively, based on instructions from the host apparatus 110c. The host apparatuses 110a, 110b, and 110c are connected to a server apparatus 150 via a network N4, such as the Internet or the like.

In the following description, the substrate processing apparatuses 120a1 through 120a3, 120b1, 120b2, 120c1, and 120c2 are collectively referred to as substrate processing apparatus 120. The control devices 121a1 through 121a3, 121b1, 121b2, 121c1, and 121c2 are collectively referred to as control device 121. Further, the host apparatuses 110a, 110b, and 110c are collectively referred to as host apparatus 110.

Various kinds of data managed by the substrate processing apparatuses 120a1 through 120a3, the substrate processing apparatuses 120b1 and 120b2, and the substrate processing apparatuses 120c1 and 120c2 are stored in the substrate processing apparatuses 120a1 through 120a3, the substrate processing apparatuses 120b1 and 120b2, and the substrate processing apparatuses 120c1 and 120c2, respectively.

An analysis apparatus 140 is connected to the substrate processing apparatuses 120 including the substrate processing apparatus 120al, and acquires accumulated data accumulated in each of the substrate processing apparatuses 120. Although the example of FIG. 1 illustrates a state where the analysis apparatus 140 is connected to the substrate processing apparatus 120al, the present disclosure is not limited thereto. Hereinafter, in the present embodiment, a case where the analysis apparatus 140 is connected to the substrate processing apparatus 120al will be described in detail.

The analysis apparatus 140 is an example of an information processing apparatus communicable with a substrate processing apparatus that processes a target object. Further, the substrate processing system 100 illustrated in FIG. 1 is merely an example, and various other system configuration examples are possible depending on the use or purpose. The classification of the apparatuses or devices, such as the substrate processing apparatus 120, the control device 121, the host apparatus 110, the analysis apparatus 140, and the server apparatus 150 illustrated in FIG. 1 is merely an example. For example, the number of the substrate processing apparatuses 120, the number of the control devices 121, the number of the analysis apparatuses 140, the number of the plants, the number of the host apparatuses 110, or the like are merely examples, and the present disclosure is not limited thereto.

For example, the substrate processing system 100 may have various configurations, such as a configuration in which at least two of the substrate processing apparatus 120, the control device 121, the host apparatus 110, the analysis apparatus 140, and the server apparatus 150 are integrated, or a configuration in which the substrate processing apparatus 120, the control device 121, the host apparatus 110, the analysis apparatus 140, and the server apparatus 150 are further divided. For example, the control device 121 may be configured to collectively control a plurality of substrate processing apparatuses 120, or may be provided in one-to-one correspondence with the substrate processing apparatuses 120, or may be integrated with the substrate processing apparatuses 120.

In addition, although the analysis apparatus 140 is connected to the substrate processing device 120al in the example described above, the analysis apparatus 140 may also be connected to another substrate processing device 120. Another analysis apparatus 140 may be connected in a one-to-one correspondence with another substrate processing device 120a2 or the like.

The analysis apparatus 140 may be implemented by the host apparatus 110 or the server apparatus 150. In addition, the analysis apparatus 140 may be implemented by the control device 121. The analysis apparatus 140 may be implemented by a control device that collectively controls a plurality of control devices 121.

### <Substrate Processing Apparatus>

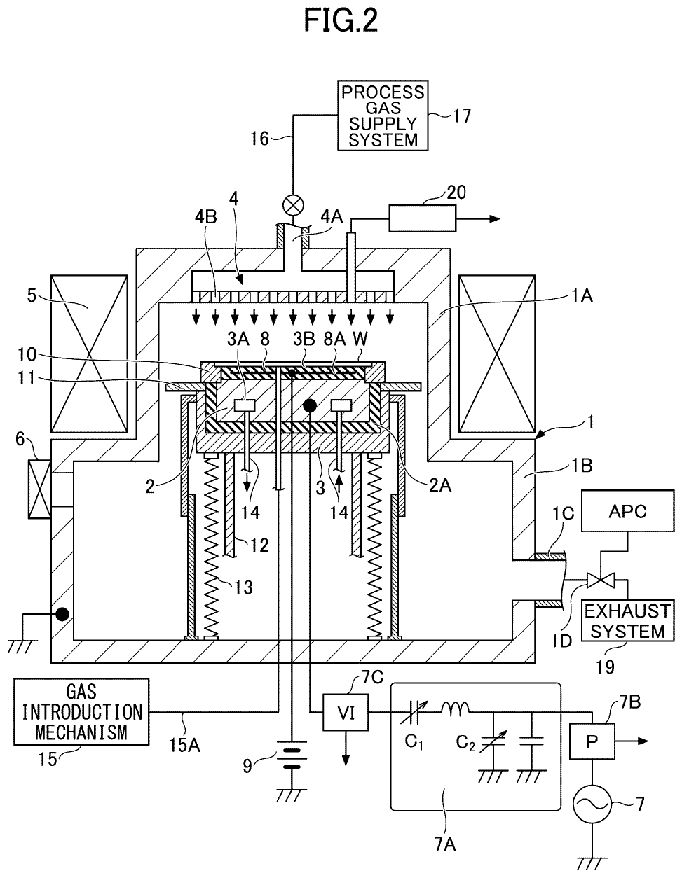

An example of the substrate processing apparatus according to the present embodiment will be described with reference to FIG. 2. FIG. 2 is a diagram illustrating an example of the substrate processing apparatus according to the present embodiment.

As illustrated in FIG. 2, the substrate processing apparatus 120 of the present embodiment includes a processing chamber 1 made of aluminum, which is an example of a chamber, a lower electrode 2 disposed inside the processing chamber 1, a support 3 made of aluminum and capable of being raised and lowered, and a shower head 4 that supplies a process gas, for example. The support 3 supports the lower electrode 2 through an insulating material 2A. The shower head 4 is disposed above the support 3 and serves also as an upper electrode (hereinafter, also referred to as an “upper electrode 4”).

An upper part of the processing chamber 1 is formed as an upper chamber 1A having a small diameter, and a lower part of the processing chamber 1 is formed as a lower chamber 1B having a large diameter. The upper chamber 1A is surrounded by a dipole ring magnet 5. The dipole ring magnet 5 is formed by housing multiple anisotropic segmented columnar magnets within a casing made of a ring-shaped magnetic material. The dipole ring magnet 5 forms a uniform horizontal magnetic field directed in one direction as a whole inside the upper chamber 1A.

An inlet and outlet port through which a wafer W, which is an example of a substrate, is loaded into and unloaded from the processing chamber 1, is formed in an upper portion of the lower chamber 1B. A gate valve 6 is attached to the inlet and outlet port of the lower chamber 1B. A high-frequency power source 7 is connected to the lower electrodes 2 via an integrator 7A. By applying high-frequency power P from the high-frequency power source 7 to the lower electrode 2, a vertical electric field is formed between the upper electrode 4 and the lower electrode 2 inside the upper chamber 1A. The high-frequency power P is detected via a power meter 7B connected between the high-frequency power source 7 and the integrator 7A.

An electric measuring instrument (for example, a VI probe) 7C is attached to the integrator 7A on the side of the lower electrode 2 (the side from which the high-frequency voltage is output). The electric measuring instrument 7C detects a high-frequency voltage V and a high-frequency current I of a fundamental wave and a harmonic wave based on plasma generated inside the upper chamber 1A due to the high-frequency power P applied to the lower electrode 2. The integrator 7A includes variable capacitors C1 and C2, a capacitor C, and a coil L, for example, and performs an impedance matching via the variable capacitors C1 and C2.

An electrostatic chuck 8 is disposed on an upper surface of the lower electrode 2. A DC power source 9 is connected to an electrode plate 8A of the electrostatic chuck 8. A high voltage is applied to the electrode plate 8A from the DC power source 9 under a high vacuum, so that the wafer W is electrostatically attracted by the electrostatic chuck 8.

An edge ring 10 is disposed on an outer periphery of the lower electrode 2. The edge ring 10 collects the plasma generated inside the upper chamber 1A on the wafer W. An exhaust ring 11 attached to an upper portion of the support 3 is disposed below the edge ring 10. A plurality of holes are formed in the exhaust ring 11 at equal intervals in a circumferential direction over the entire circumference. A gas inside the upper chamber 1A is exhausted to the lower chamber 1B through the holes in the exhaust ring 11.

The support 3 is movable up and down between the upper chamber 1A and the lower chamber 1B through a ball screw mechanism 12 and a bellows 13. In a case where the wafer W is supplied onto the lower electrode 2, the lower electrode 2 is lowered to the lower chamber 1B through the support 3, the gate valve 6 is opened, and the wafer W is supplied onto the lower electrode 2 through a transport mechanism.

A coolant flow path 3A connected to a coolant pipe 14 is formed inside the support 3. The wafer W is adjusted to a predetermined temperature by circulating a coolant in the coolant flow path 3A through the coolant pipe 14. Further, a gas flow path 3B is formed in each of the support 3, the insulating material 2A, the lower electrode 2, and the electrostatic chuck 8. He gas is supplied as a backside gas at a predetermined pressure from a gas introduction mechanism 15 to a narrow gap between the electrostatic chuck 8 and the wafer W through a gas pipe 15A, and a thermal conductivity between the electrostatic chuck 8 and the wafer W is increased through the He gas.

A gas inlet 4A is formed on an upper surface of the shower head 4. A process gas supply system 17 is connected to the gas inlet 4A through a pipe 16. The process gas supply system 17 is used as a gas supply source for supplying a noble gas for plasma generation, a processing gas used for an oxidation process, a nitridation process, a film (i.e. a layer) forming (or film deposition) process, an etching process, an ashing process, or the like, for example. The process gas supply system 17 in the present embodiment includes at least a N2 gas supply source. The N2 gas supply source includes an on/off valve and a mass flow controller provided in a middle of the pipe 16. The N2 gas supply source supplies N2 gas (nitrogen gas) to the shower head 4 at a set flow rate through the on/off valve and the mass flow controller. The type, flow rate, or the like of the gas supplied into the processing chamber 1 are controlled by the on/off valve and the mass flow controller.

A plurality of holes 4B are uniformly arranged over the entire lower surface of the shower head 4. The process gas is supplied from the shower head 4 into the upper chamber 1A through the plurality of holes 4B. An exhaust pipe 1C is connected to an exhaust hole in a lower portion of the lower chamber 1B. The processing chamber 1 is exhausted through an exhaust system 19 including a vacuum pump or the like connected to the exhaust pipe 1C, thereby maintaining a predetermined gas pressure. An automatic pressure control (APC) valve 1D is provided on exhaust pipe 1C, and an opening degree of the APC valve 1D is automatically adjusted according to the gas pressure inside the processing chamber 1.

For example, a spectrometer 20 (hereinafter referred to as an “optical measuring instrument”) for detecting plasma emission inside the processing chamber 1 is installed in the shower head 4. By monitoring the plasma state based on optical data (hereinafter referred to as “plasma emission data”) related to a specific wavelength obtained by the optical measuring instrument 20, the end point of the plasma processing can be detected.

### <Hardware Configuration>

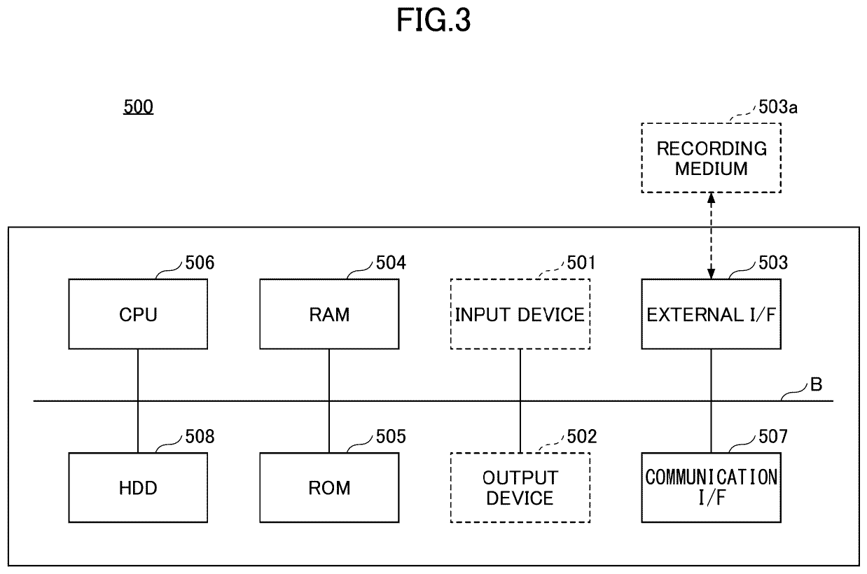

The host apparatus 110, the control device 121, the analysis apparatus 140, and the server apparatus 150 included in the substrate processing system 100 illustrated in FIG. 1 may be implemented by a computer having a hardware configuration illustrated in FIG. 3, for example. FIG. 3 is a block diagram illustrating an example of the hardware configuration of the computer according to the present embodiment.

As illustrated in FIG. 3, a computer (i.e., processing circuitry) 500 according to the present embodiment includes an input device 501, an output device 502, an external interface (I/F) 503, a random access memory (RAM) 504, a read only memory (ROM) 505, a central processing unit (CPU) 506, a communication I/F 507, a hard disk drive (HDD) 508, or the like, which are connected to one another via a bus B. The input device 501 and the output device 502 may be connected to the bus B, or to the computer 500, as required.

The input device 501 is a keyboard, a mouse, a touchscreen panel, or the like, and is used by an operator or the like to input various operation signals. The output device 502 is a display device or the like, and displays a processing result of the computer 500. The communication I/F 507 is an interface that connects the computer 500 to a network. The HDD 508 is an example of a nonvolatile storage device that stores one or more programs and data.

The external I/F 503 is an interface that connects the computer 500 to an external device. The computer 500 can read and/or write data from/to a recording medium 503a, such as a secure digital (SD) memory card or the like, via the external I/F 503. The ROM 505 is an example of a nonvolatile semiconductor memory (storage device) that stores one or more programs and data. The RAM 504 is an example of a volatile semiconductor memory (storage device) that temporarily stores one or more programs and data.

The CPU 506 is a computing device or processor (processing circuitry) that reads one or more programs and data from a storage device or memory, such as the ROM 505, the HDD 508, or the like and loads the read one or more programs and data into the RAM 504, so as to execute processes to control the entire computer 500 and implement functions of the computer 500. A non-transitory computer-readable storage medium may be used as the storage device or memory.

### <Functional Configuration>

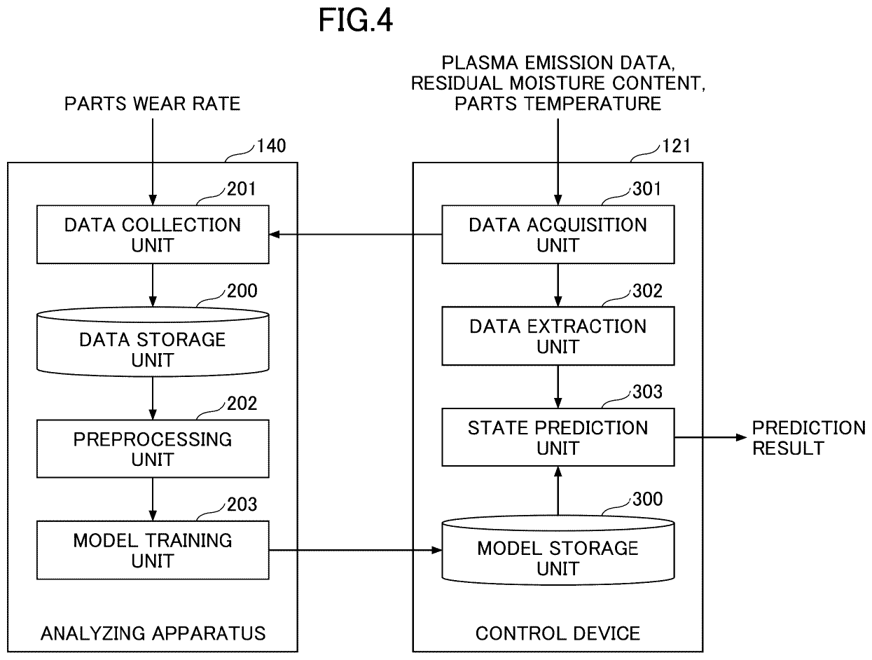

A functional configuration of the substrate processing system according to the present embodiment will be described with reference to FIG. 4. FIG. 4 is a diagram illustrating an example of a functional configuration of the substrate processing system according to the present embodiment.

### <<Analysis Apparatus>>

As illustrated in FIG. 4, the analysis apparatus 140 according to the present embodiment includes a data storage unit 200, a data collection unit 201, a preprocessing unit 202, and a model training unit 203.

The data storage unit 200 is implemented by the RAM 504 or the HDD 508 illustrated in FIG. 3, for example. The data collection unit 201, the preprocessing unit 202, and the model training unit 203 are implemented by the CPU 506 illustrated in FIG. 3 executing the one or more programs loaded into the RAM 504, for example.

The data storage unit 200 stores training data for training a prediction model. The training data includes plasma emission data obtained by measuring plasma emission in the processing chamber 1 of the substrate processing apparatus 120, and chamber state data indicating a state in the processing chamber 1 of the substrate processing apparatus 120. The training data is collected by the data collection unit 201.

The plasma emission data is a plasma emission spectrum data of the N2 gas, for example. The plasma emission spectrum data preferably includes a wavelength band (wavelength range) from 200 nm to 900 nm.

The chamber state data includes an amount of residual gas (H₂O) inside the processing chamber 1 (hereinafter, also referred to as a “residual moisture content”), a parts wear rate of parts (or components) present inside the processing chamber 1, and a parts temperature of parts (or components) present inside the processing chamber 1, for example. The parts wear rate includes a thickness of the edge ring 10 or a surface roughness of an upper electrode plate constituting the upper electrode 4, for example. The parts temperature includes an ambient temperature around the edge ring 10 or an ambient temperature around the upper electrode plate, for example.

The plasma emission data included in the training data is data obtained by measuring plasma emission when a plasma process is performed inside a chamber in a known chamber state. The chamber state data included in the training data is data indicating the chamber state when the plasma emission data is acquired.

The data collection unit 201 collects the training data. The data collection unit 201 acquires the plasma emission data, the residual moisture content, and the parts temperature from the control device 121. In addition, the data collection unit 201 acquires the parts wear rate input by a user. The data collection unit 201 stores the collected plasma emission data and the collected chamber state data in the data storage unit 200 in association with each other.

The preprocessing unit 202 performs a predetermined preprocessing on the training data. The preprocessing may include noise reduction or auto scaling of the plasma emission data, for example. The preprocessing unit 202 may extract a predetermined wavelength band from the plasma emission data included in the training data. The preprocessing unit 202 may extract a wavelength band according to the chamber state to be predicted.

The model training unit 203 trains a prediction model for predicting the chamber state based on the training data stored in the data storage unit 200. The prediction model is a regression model that has learned a relationship between the plasma emission data and the chamber state. The model training unit 203 trains the regression model in which the plasma emission data is an explanatory variable and the chamber state is an objective variable for each chamber state to be predicted.

### <<Control Device>>

As illustrated in FIG. 4, the control device 121 in the present embodiment includes a model storage unit 300, a data acquisition unit 301, a data extraction unit 302, and a state prediction unit 303.

The model storage unit 300 is implemented by the RAM 504 or the HDD 508 illustrated in FIG. 3, for example. The data acquisition unit 301, the data extraction unit 302, and the state prediction unit 303 are implemented by the CPU 506 illustrated in FIG. 3 executing the one or more programs loaded into the RAM 504, for example.

The model storage unit 300 stores the trained prediction model. The prediction model is trained by the analysis apparatus 140 and output to the control device 121.

When training the prediction model, the data acquisition unit 301 acquires the plasma emission data, the residual moisture content, and the parts temperature to be trained, from the substrate processing apparatus 120. The data acquisition unit 301 transmits the plasma emission data, the residual moisture content, and the parts temperature to be trained to the analysis apparatus 140. In addition, when predicting the chamber state, the data acquisition unit 301 acquires plasma emission data to be predicted.

For example, the data acquisition unit 301 acquires the plasma emission data output from the optical measuring instrument 20. Further, for example, the data acquisition unit 301 acquires, as the residual moisture content, residual gas data output from a residual gas measuring instrument provided in the substrate processing apparatus 120. The data acquisition unit 301 acquires temperature data output from a temperature sensor installed near each part inside the processing chamber 1, as the parts temperature.

The data extraction unit 302 extracts a predetermined wavelength band from the plasma emission data acquired by the data acquisition unit 301. The data extraction unit 302 may extract a wavelength band according to the chamber state to be predicted.

The state prediction unit 303 predicts a chamber state to be predicted by inputting the plasma emission data acquired by the data acquisition unit 301 to the prediction model read from the model storage unit 300. The state prediction unit 303 may predict the chamber state by inputting the plasma emission data extracted by the data extraction unit 302 to the prediction model. The state prediction unit 303 outputs a prediction result of the chamber state to the output device 502 of the control device 121 or the like. The state prediction unit 303 may transmit the prediction result of the chamber state to the analysis apparatus 140.

### <Processing Procedure>

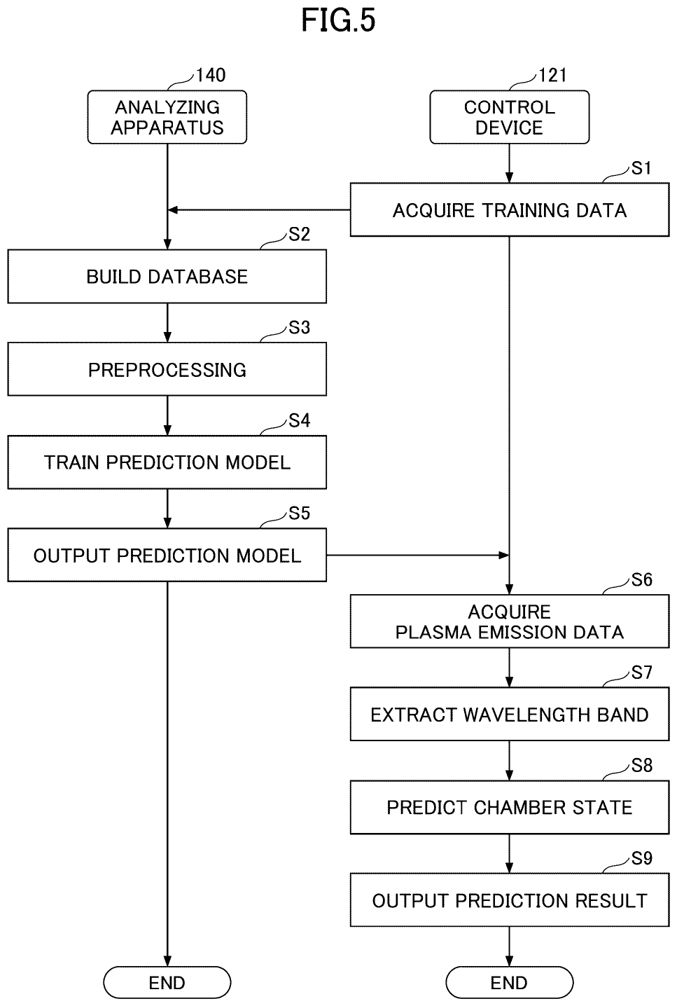

A substrate processing method performed by the substrate processing system 100 according to the present embodiment will be described with reference to FIG. 5 through FIG. 7. FIG. 5 is a flow chart illustrating an example of the substrate processing method according to the present embodiment.

In step S1, the data acquisition unit 301 of the control device 121 acquires the plasma emission data, the residual moisture content, and the parts temperature to be trained. The plasma emission data, the residual moisture content, and the parts temperature to be trained are data measured when a plasma processing is performed without placing the wafer W inside the processing chamber 1 in a known chamber state. The data acquisition unit 301 transmits the acquired plasma emission data, the residual moisture content, and the parts temperature to the analysis apparatus 140.

In step S2, the data collection unit 201 of the analysis apparatus 140 receives the plasma emission data, the residual moisture content, and the parts temperature from the control device 121. The data collection unit 201 acquires the parts wear rate input by the user. Next, the data collection unit 201 generates chamber state data including the residual moisture content, the parts wear rate, and the parts temperature. Then, the data collection unit 201 stores the plasma emission data and the chamber state data in the data storage unit 200 in association with each other, thereby building a database.

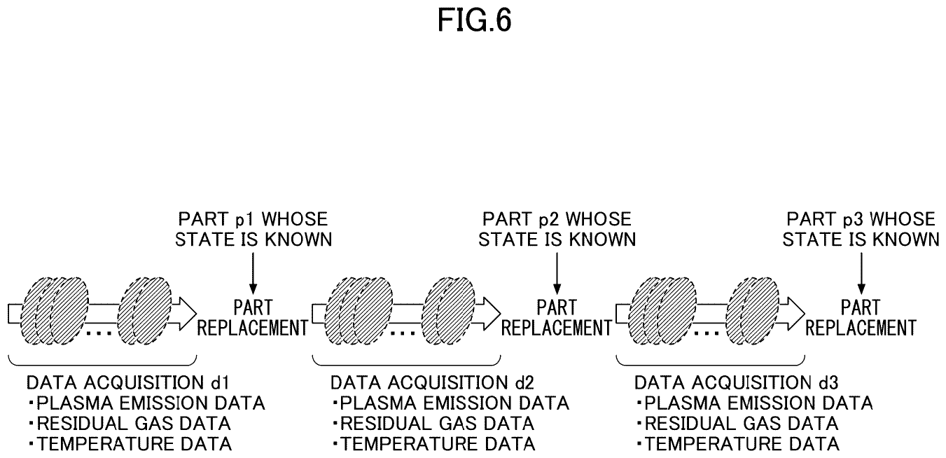

Next, a training data collection procedure will be described in more detail with reference to FIG. 6. As illustrated in FIG. 6, in the training data collection procedure, a plurality of parts whose states are known are prepared. Three edge rings whose thicknesses have been measured and three upper electrode plates whose surface roughnesses have been measured are prepared as the plurality of parts whose states are known.

First, a part whose state is known is installed in the substrate processing apparatus 120. Next, the plasma processing is performed a plurality of times without placing the wafer W inside the processing chamber 1. In this state, the plasma emission data, the residual moisture content, and the parts temperature are measured every time the plasma processing is performed. Thereafter, the part is replaced with another part whose state is known, and the plasma processing is performed a plurality of times again, and such processes are repeated twice.

In the example illustrated in FIG. 6, there are three kinds of known parts p1, p2, and p3, and the part replacement and the data measurement (or data acquisition) d1, d2, and d3 are repeated three times, but the number of repetitions is not limited to three. The plasma emission data for the known chamber state can be collected by the procedure described above.

The plasma process is preferably performed at low power. For example, plasma may be generated by applying a high-frequency power P lower than or equal to 1 kW or lower than or equal to 500 W to the lower electrode 2. The plasma process may be performed for a short time. For example, the plasma may be generated by applying the high-frequency power P to the lower electrode 2 for 1 minute or less or 10 seconds or less. The plasma emission data may be an average of signals output from the optical measurement device. For example, the plasma emission may be measured for 30 seconds, and the average of the measured plasma emissions may be used as the plasma emission data.

In step S3, the preprocessing unit 202 of the analysis apparatus 140 reads the training data from the data storage unit 200. Next, the preprocessing unit 202 performs a predetermined preprocessing on the read training data. Subsequently, the preprocessing unit 202 extracts a predetermined wavelength band from the plasma emission data. The wavelength band that is extracted is in a range from 200 nm to 900 nm, for example. The wavelength band that is extracted may be in a range from 200 nm to 800 nm, for example. Then, the preprocessing unit 202 sends the preprocessed training data after the preprocessing to the model training unit 203.

The preprocessing unit 202 may extract a wavelength band according to a chamber state to be predicted from the plasma emission data. The wavelength band according to the chamber state can be determined by analyzing a wavelength band having a strong influence on a prediction result obtained from a prediction model for predicting the chamber state. In a case where an influence greater than or equal to a certain level is observed in all the wavelength bands, the wavelength band according to the chamber state does not need to be extracted from the plasma emission data.

In step S4, the model training unit 203 of the analysis apparatus 140 receives the preprocessed training data from the preprocessing unit 202. Next, the model training unit 203 trains the prediction model for predicting the chamber state to be predicted, based on the training data after the preprocessing.

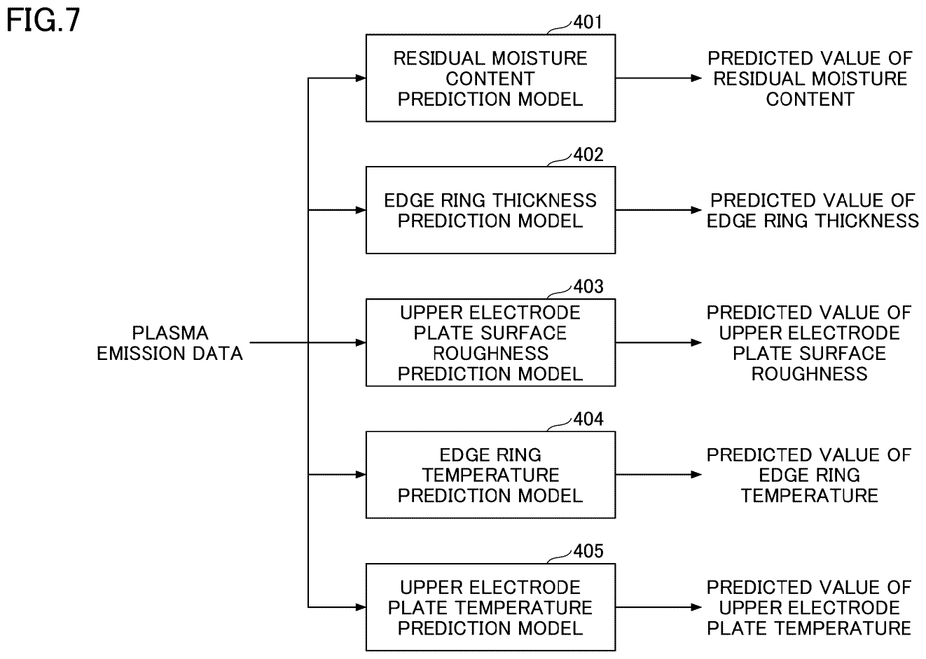

The model training unit 203 trains a regression model in which the plasma emission data is an explanatory variable and the chamber state is an objective variable, for each chamber state to be predicted. FIG. 7 is a diagram illustrating an example of the prediction model according to the present embodiment. As illustrated in FIG. 7, in the present embodiment, the residual moisture content, the edge ring thickness, the upper electrode plate surface roughness, the edge ring temperature, and the upper electrode plate temperature are used as the chamber state to be predicted.

In this case, the model training unit 203 trains a residual moisture content prediction model 401, an edge ring thickness prediction model 402, an upper electrode plate surface roughness prediction model 403, an edge ring temperature prediction model 404, and an upper electrode plate temperature prediction model 405. The residual moisture content prediction model 401 is a multivariate analysis model (or a multivariate regression model) in which the plasma emission data is an explanatory variable and the residual moisture content is an objective variable. The edge ring thickness prediction model 402 is a multivariate analysis model in which the plasma emission data is an explanatory variable and the edge ring thickness is an objective variable. The upper electrode plate surface roughness prediction model 403 is a multivariate analysis model in which the plasma emission data is an explanatory variable and the upper electrode plate surface roughness is an objective variable. The edge ring temperature prediction model 404 is a multivariate analysis model in which the plasma emission data is an explanatory variable and the edge ring temperature is an objective variable. The upper electrode plate temperature prediction model 405 is a multivariate analysis model in which the plasma emission data is an explanatory variable and the upper electrode plate temperature is an objective variable.

The prediction model may be a different type of regression model according to the chamber state to be predicted. For example, the different types of regression model that are available include:
Linear regression;
Lasso regression;
Ridge regression;
Elastic net;
Least angle regression;
Lasso least angle regression;
Orthogonal matching pursuit;
Bayesian ridge regression;
Automatic relevance determination;
Passive aggressive regression (passive aggressive regressor);
Random sample consensus;
Theil-Sen regression (Theil-Sen regressor);
Partial least squares regression (partial least squares regressor);
Huber regression (Huber regressor);
Kernel ridge regression (Kernel ridge regressor);
Support vector regression;
K neighbors regression (K neighbors regressor);
Decision tree regression (decision tree regressor);
Random forest regression (random forest regressor);
Extra trees regression (extra trees regressor);
Adaptive boost regression (AdaBoost Regressor);
Gradient boosting regression (gradient boosting regressor);
Multi-Layer perceptron regression (multi-layer perceptron regressor);
Extreme gradient boosting;
Light gradient boosting machine;
Category boost regression (CatBoost regressor);
   or the like. In the present embodiment, the random forest regression (random forest regressor) is used as an example.

In step S5, the model training unit 203 of the analysis apparatus 140 outputs the trained prediction model. The analysis apparatus 140 transmits the trained prediction model to the control device 121. The control device 121 receives the trained prediction model from the analysis apparatus 140. Then, the control device 121 stores the received prediction model in the model storage unit 300.

In step S6, the data acquisition unit 301 of the control device 121 acquires the plasma emission data to be predicted. The plasma emission data to be predicted is the data measured when the plasma processing is performed inside the processing chamber 1 in an unknown chamber state. When measuring the plasma emission data to be predicted, the wafer W may or may not be placed inside the processing chamber 1. Further, the data acquisition unit 301 sends the acquired plasma emission data to the data extraction unit 302.

In step S7, the data extraction unit 302 of the control device 121 receives the plasma emission data from the data acquisition unit 301. Next, the data extraction unit 302 extracts the predetermined wavelength band from the received plasma emission data. The wavelength band to be extracted is the same as the wavelength band to be extracted in the preprocessing unit 202. Further, the data extraction unit 302 sends the extracted plasma emission data to the state prediction unit 303.

The data extraction unit 302 may extract the wavelength band according to the chamber state to be predicted from the plasma emission data, similar to the preprocessing unit 202. In addition, the data extraction unit 302 does not need to extract the wavelength band according to the chamber state from the plasma emission data, similar to the preprocessing unit 202.

In step S8, the state prediction unit 303 of the control device 121 receives the plasma emission data from the data extraction unit 302. Next, the state prediction unit 303 reads the trained prediction model from the model storage unit 300. Subsequently, the state prediction unit 303 predicts the chamber state to be predicted by inputting the plasma emission data to the prediction model.

In step S9, the state prediction unit 303 of the control device 121 acquires the prediction result of the chamber state output from the prediction model. Next, the state prediction unit 303 outputs the prediction result of the chamber state to the output device 502 of the control device 121 or the like. The state prediction unit 303 may transmit the prediction result of the chamber state to the analysis apparatus 140. When the analysis apparatus 140 receives the prediction result of the chamber state, the analysis apparatus 140 outputs the prediction result of the chamber state to the output device 502 of the analysis apparatus 140 or the like.

### <Analysis Results>

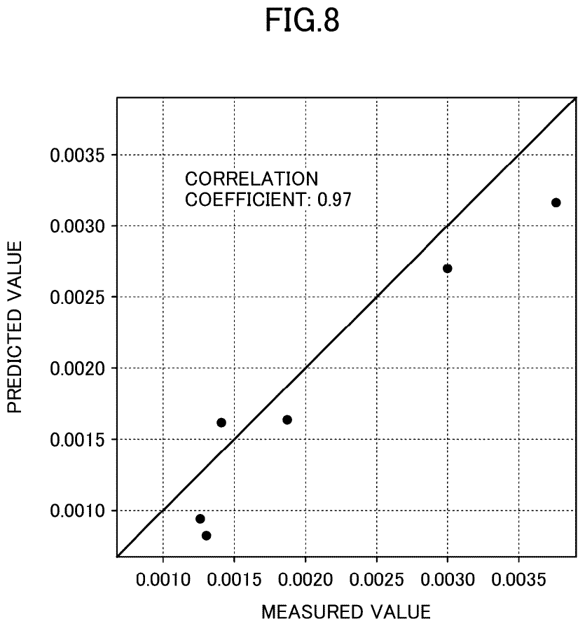

Analysis results of the prediction model in the present embodiment will be described with reference to FIG. 8 through FIG. 11.

FIG. 8 is a diagram illustrating an example of prediction accuracy for the residual moisture content. FIG. 8 is a graph in which measured values and predicted values of the residual moisture content acquired in a plurality of chamber states are plotted, with the abscissa indicating the measured value of the residual moisture content and the ordinate indicating the predicted value of the residual moisture content. The measured value of the residual moisture content is an objective variable y of the regression model. In the graph illustrated in FIG. 8, a correlation coefficient between the measured value and the predicted value was 0.97. It was confirmed from FIG. 8 that the prediction model according to the present embodiment can predict the residual moisture content with a high accuracy.

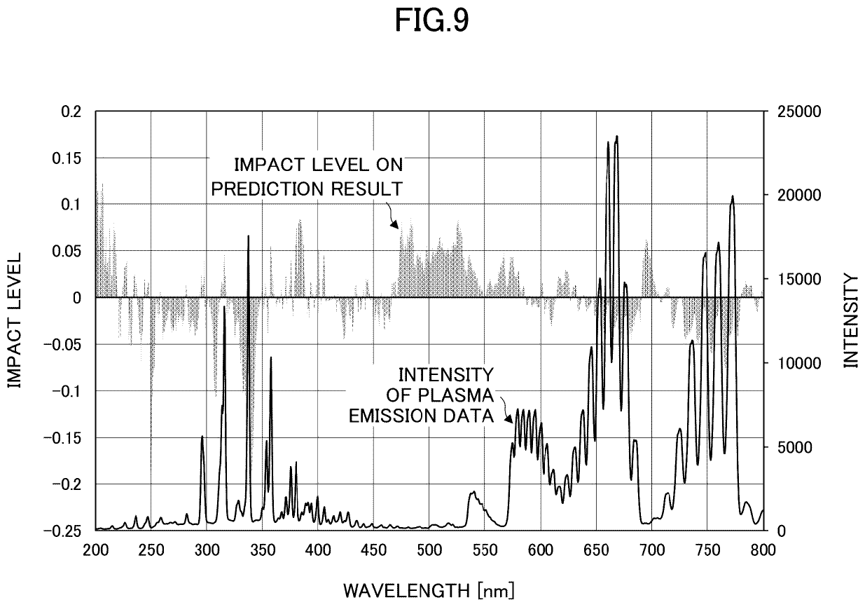

FIG. 9 is a diagram illustrating an example of impact levels of wavelength bands on the residual moisture content prediction illustrated in FIG. 8. FIG. 9 is a graph illustrating an intensity of plasma emission data and the impact levels on the prediction result for each wavelength when the residual moisture content is predicted for one plasma emission data. As illustrated in FIG. 9, the impact level of a certain level or higher is illustrated in the entire range from 200 nm to 800 nm of the plasma emission data, and it can be observed that the entire plasma emission data indicates the residual moisture content.

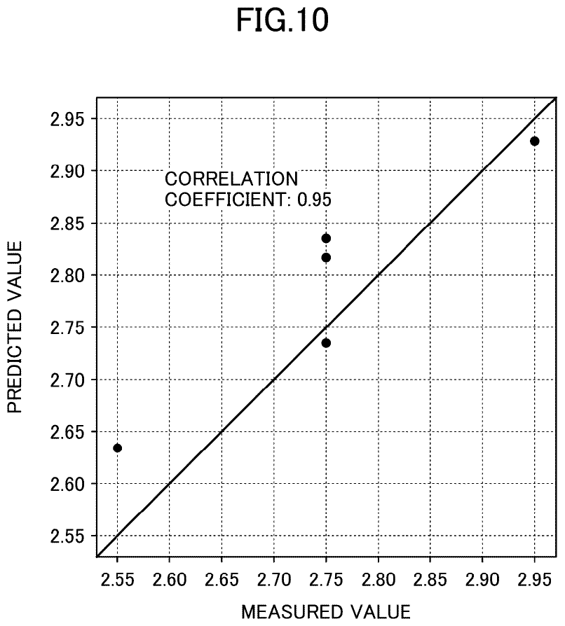

FIG. 10 is a diagram illustrating an example of a prediction accuracy for the parts wear rate. In this example, the edge ring thickness is used as the parts wear rate. FIG. 10 is a graph in which measured values and predicted values of the edge ring thickness acquired in a plurality of chamber states are plotted, with the abscissa indicating the measured value of the edge ring thickness and the ordinate indicating the predicted value of the residual moisture content. In the graph illustrated in FIG. 10, a correlation coefficient between the measured value and the predicted value was 0.95. It was confirmed from FIG. 10 that the prediction model according to the present embodiment can predict the edge ring thickness with a high accuracy.

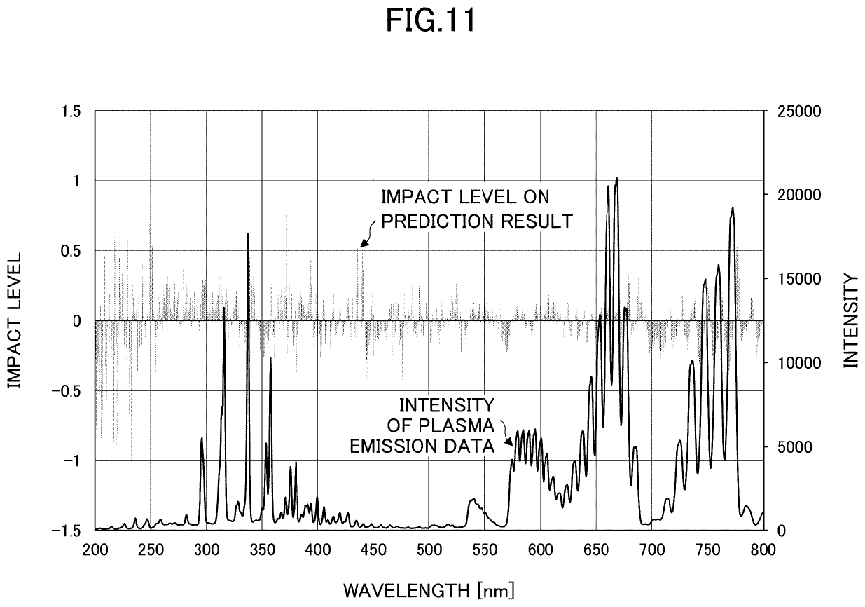

FIG. 11 is a diagram illustrating an example of impact levels of wavelength bands on the parts wear rate prediction illustrated in FIG. 10. FIG. 11 is a graph illustrating the intensity of plasma emission data and the impact level on the prediction result for each wavelength when the edge ring thickness is predicted for one plasma emission data. As illustrated in FIG. 11, the impact level of a certain level or higher is illustrated in the entire range from 200 nm to 800 nm of the plasma emission data, and it can be seen that the entire plasma emission data indicates the edge ring thickness.

In the examples illustrated in FIG. 9 and FIG. 11, the entire plasma emission data represents the chamber state, but the impact level may be concentrated on a specific wavelength depending on the chamber state to be predicted. In this case, if the wavelength band having a high impact level is extracted and input to the prediction model in the preprocessing unit 202 and the data extraction unit 302, it may be expected that the chamber state can be predicted with a higher accuracy.

### Advantageous Features of Embodiment

The control device 121 in the present embodiment predicts the state inside the chamber, using the trained prediction model that has learned the relationship between the plasma emission data inside the chamber and the chamber state data indicating the state inside the chamber. Hence, according to the substrate processing system 100 of the present embodiment, the state inside the chamber can be predicted based on the plasma emission data.

Because the plasma emission data can be measured by the optical measuring instrument 20 included in an existing substrate processing apparatus, it is unnecessary to provide a dedicated sensor for measuring the state inside the chamber. Thus, according to the substrate processing system 100 of the present embodiment, a virtual sensor for estimating the state inside the chamber can be implemented in a simple manner at a low cost.

The plasma emission spectrum in the present embodiment may be a plasma emission spectrum of the N2 gas. Because the N₂ gas is used in many substrate processes, it is unnecessary to provide a dedicated gas supply mechanism for measuring the state inside the chamber. Hence, according to the substrate processing system 100 of the present embodiment, a virtual sensor for estimating the state inside the chamber can be implemented in a simple manner at a low cost.

The control device 121 in the present embodiment may predict the state inside the chamber by inputting the plasma emission data, from which the wavelength band according to the state inside the chamber to be predicted is extracted, to the prediction model. The wavelength band that affects the prediction result may differ depending on the state inside the chamber to be predicted. Thus, according to the substrate processing system 100 of the present embodiment, the state inside the chamber can be predicted with a high accuracy.

The state inside the chamber in the present embodiment may be the residual moisture content inside the chamber, the parts wear rate of parts present inside the chamber, or the parts temperature of parts present inside the chamber. The residual moisture content, the parts wear rate, or the parts temperature is data that is difficult to actually measure during operation. For this reason, according to the substrate processing system 100 of the present embodiment, the state inside the chamber can be predicted efficiently.

For example, if the parts wear rate can be estimated by the virtual sensor, a replacement timing of each part can be detected without removing each part from the substrate processing apparatus 120 and measuring the parts wear rate of each part. Further, for example, if the residual moisture content inside the chamber can be estimated by the virtual sensor, it is possible to easily determine whether or not the inside of the chamber is in a state suitable for the plasma processing.

According to an aspect of the present disclosure, it is possible to predict the state inside the chamber based on the plasma emission data.

### Supplement

The substrate processing system according to the embodiment disclosed herein is illustrative and non-restrictive in all respects. The embodiments can be modified and improved in various forms without departing from the scope and spirit of the present disclosure. The matters described in the above embodiments may be modified in other ways without departing from the scope of the present disclosure, and may be combined with each other without departing from the scope of the present disclosure.

The substrate processing apparatus that performs the processes including the substrate processing method of the present disclosure is not limited to the substrate processing apparatus 120 described above. The substrate processing apparatus may be any type of apparatus, such as an atomic layer deposition (ALD) apparatus, a capacitively coupled plasma (CCP) apparatus, an inductively coupled plasma (ICP) apparatus, a radial line slot antenna (RLSA) apparatus, an electron cyclotron resonance plasma (ECRP) apparatus, or a helicon wave plasma (HWP) apparatus.

### Appended Clauses

Various aspects of the subject matter described in the embodiments may be set out non-exhaustively in the following numbered clauses:

### (Clause 1)

A substrate processing system comprising:
a data acquisition unit configured to acquire plasma emission data inside a chamber; and
a state prediction unit configured to predict a state inside the chamber by inputting the plasma emission data acquired by the data acquisition unit to a trained model that has learned a relationship between the plasma emission data and information indicating the state inside the chamber.

### (Clause 2)

The substrate processing system according to clause 1, wherein the plasma emission data is plasma emission spectrum data of nitrogen gas.

### (Clause 3)

The substrate processing system according to clause 2, wherein the plasma emission spectrum is included in a wavelength band of 200 nm or more and 900 nm or less.

### (Clause 4)

The substrate processing system according to clause 3, further comprising:
a data extraction unit configured to extract a wavelength band according to a chamber state to be predicted from the plasma emission spectrum data,
wherein the state prediction unit predicts the state inside the chamber by inputting the plasma emission spectrum data extracted by the data extraction unit to the trained model.

### (Clause 5)

The substrate processing system according to any one of clauses 1 to 4, wherein the state inside the chamber is a residual moisture content inside the chamber.

### (Clause 6)

The substrate processing system according to any one of clauses 1 to 4, wherein the state inside the chamber is a parts wear rate of parts present inside the chamber.

### (Clause 7)

The substrate processing system according to any one of clauses 1 to 4, wherein the state inside the chamber is a parts temperature of parts present inside the chamber.

### (Clause 8)

The substrate processing system according to any one of clauses 1 to 7, wherein the trained model is a multivariate analysis model.

### (Clause 9)

The substrate processing system according to clause 8, wherein the multivariate analysis model is a random forest regression.

### (Clause 10)

A substrate processing system comprising:
a data collection unit configured to collect plasma emission data inside a chamber and information indicating a state inside the chamber; and
a model training unit configured to train a model for predicting the information indicating the state inside the chamber when the plasma emission data is input, based on training data including the plasma emission data and the information indicating the state inside the chamber.

### (Clause 11)

A substrate processing method implemented by a computer which performs a process including:
acquiring plasma emission data inside a chamber;
predicting a state inside the chamber by inputting the acquired plasma emission data to a trained model that has learned a relationship between the plasma emission data and information indicating the state inside the chamber.

### (Clause 12)

A non-transitory computer-readable storage medium storing a program which, when executed by a computer, causes the computer to perform a process including:
acquiring plasma emission data inside a chamber;
predicting a state inside the chamber by inputting the acquired plasma emission data to a trained model that has learned a relationship between the plasma emission data and information indicating the state inside the chamber.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

Reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C.

No claim element herein is to be construed under the provisions of 35 U.S.C. 112(f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The scope of the invention is indicated by the appended claims, rather than the foregoing description.

What is claimed is:

1. A substrate processing system comprising:
a substrate processing apparatus including a chamber; and
control circuitry, coupled to the substrate processing apparatus, and including a memory that stores a program and data, and processing circuitry configured to perform control to:
acquire plasma emission data inside the chamber; and
predict a state inside the chamber by inputting the plasma emission data acquired by the acquiring to a trained model that has learned a relationship between the plasma emission data and information indicating the state inside the chamber.

2. The substrate processing system as claimed in claim 1, wherein the plasma emission data is plasma emission spectrum data of nitrogen gas.

3. The substrate processing system as claimed in claim 2, wherein the plasma emission spectrum is included in a wavelength band of 200 nm or more and 900 nm or less.

4. The substrate processing system as claimed in claim 3, wherein the processing circuitry is configured to perform control to:
extract a wavelength band according to a chamber state to be predicted from the plasma emission spectrum data,
wherein the predicting predicts the state inside the chamber by inputting the plasma emission spectrum data extracted by the extracting to the trained model.

5. The substrate processing system as claimed in claim 1, wherein the state inside the chamber is a residual moisture content inside the chamber.

6. The substrate processing system as claimed in claim 1, wherein the state inside the chamber is a parts wear rate of parts present inside the chamber.

7. The substrate processing system as claimed in claim 1, wherein the state inside the chamber is a parts temperature of parts present inside the chamber.

8. The substrate processing system as claimed in claim 1, wherein the trained model is a multivariate analysis model.

9. The substrate processing system as claimed in claim 8, wherein the multivariate analysis model is a random forest regression.

10. A substrate processing system comprising:
a substrate processing apparatus including a chamber; and
control circuitry, coupled to the substrate processing apparatus, and including a memory that stores a program and data, and processing circuitry configured to perform control to:
collect plasma emission data inside the chamber and information indicating a state inside the chamber; and
train a model for predicting the information indicating the state inside the chamber when the plasma emission data is input, based on training data including the plasma emission data and the information indicating the state inside the chamber.

11. A substrate processing method implemented by processing circuitry which performs a process comprising:
acquiring plasma emission data inside a chamber; and
predicting a state inside the chamber by inputting the acquired plasma emission data to a trained model that has learned a relationship between the plasma emission data and information indicating the state inside the chamber.

12. The substrate processing system as claimed in claim 3, wherein the processing circuitry is configured to perform control to:
extract a wavelength band according to a chamber state to be predicted from the plasma emission spectrum data.

13. The substrate processing method as claimed in claim 11, wherein the plasma emission data is plasma emission spectrum data of nitrogen gas.

14. The substrate processing method as claimed in claim 13, wherein the plasma emission spectrum is included in a wavelength band of 200 nm or more and 900 nm or less.

15. The substrate processing method as claimed in claim 14, further comprising:
extracting a wavelength band according to a chamber state to be predicted from the plasma emission spectrum data,
wherein the predicting predicts the state inside the chamber by inputting the plasma emission spectrum data extracted by the extracting to the trained model.

16. The substrate processing method as claimed in claim 11, wherein the state inside the chamber is a residual moisture content inside the chamber.

17. The substrate processing method as claimed in claim 11, wherein the state inside the chamber is a parts wear rate of parts present inside the chamber.

18. The substrate processing method as claimed in claim 11, wherein the state inside the chamber is a parts temperature of parts present inside the chamber.

19. The substrate processing method as claimed in claim 11, wherein the trained model is a multivariate analysis model.

20. The substrate processing method as claimed in claim 19, wherein the multivariate analysis model is a random forest regression.
